(19) United States
(12) Patent Application Publication
(10) Pub. No.: US 2016/0219713 A1
(43) Pub. Date: Jul. 28, 2016

(54) ELECTRONIC COMPONENT EMBEDDED PRINTED CIRCUIT BOARD AND METHOD OF MANUFACTURING THE SAME

(71) Applicant: Samsung Electro-Mechanics Co., Ltd., Suwon-si (KR)

(72) Inventors: Tae-Seong Kim, Cheongju (KR); Bok-Hee Lee, Daejeon (KR); Ji-Hyun Lim, Daejeon (KR); Seong-Ryul Choi, Seoul (KR); Dong-Uk Lee, Cheongju (KR); Yeon-Seop Yu, Seongnam (KR)

(73) Assignee: Samsung Electro-Mechanics Co., Ltd., Suwon-si (KR)

(21) Appl. No.: 15/003,295

(22) Filed: Jan. 21, 2016

(30) Foreign Application Priority Data
Jan. 22, 2015 (KR) 10-2015-0010657

(51) Int. Cl. H05K 1/18; H05K 3/40; H05K 3/02; H05K 1/02

(52) U.S. Cl. CPC H05K 1/183; H05K 1/0204; H05K 3/4038; H05K 3/02

(57) ABSTRACT

An electronic component embedded printed circuit board and method thereof a first insulation layer, an electronic component, a second insulation layer, and a circuit layer. The first insulation layer includes a trench formed therein. The electronic component is installed in the trench. The second insulation layer is formed above the first insulation layer and the electronic component. The circuit layer is formed on the first insulation layer and on the second insulation layer.

### CROSS-REFERENCE TO RELATED APPLICATIONS

This application claims the benefit under 35 USC 119(a) of Korean Patent Application No. 10-2015-0010657, filed on Jan. 22, 2015, in the Korean Intellectual Property Office, the entire disclosure of which is incorporated herein by reference for all purposes.

### BACKGROUND

1. Field

The following description relates to an electronic component embedded printed circuit board and a method of manufacturing the same.

2. Description of Related Art

Mobile phones and other electronic apparatuses in the field of information technology have become increasingly multi-functional, lighter, thinner and smaller. A heightened demand exist to insert integrated circuits, semiconductor chips or various electronic elements, such as active devices and passive devices, in a board. Recently, various methods to embed a component in a board have been developed.

A printed circuit board (PCB) is an electrically non-conductive board having a circuit line pattern printed thereon with a conductive material, such as copper, onto which electronic elements are installed therein. In other words, a PCB refers to a circuit board in which mounting positions of various electronic components are defined and circuit patterns to connect these electronic components are printed and fixed thereon. The circuit patterns are used to receive or to install the various electronic components on the board, in a concentrated manner.

Recently, these electronic components are installed by being embedded in the PCB, which is generally referred to as an embedded PCB.

A typical embedded PCB has a trench formed in an insulation layer of the board and has various electronic components, integrated circuits and/or semiconductor chips inserted in the trench. The electronic components are stabilized and an additional insulation layer is formed by coating an adhesive resin, such as prepreg, inside the trench and on the insulation layer in which the electronic components are inserted. The electronic components are electrically connected with external device(s) through via holes or through-holes formed in the insulation layer.

The via holes or through-holes have a plated layer and pattern formed therein and thereabove for use as means for electrical connection with the electronic components embedded in the board. An electronic component embedded multilayered PCB is manufactured by successively laminating insulation layers on an upper surface and a lower surface of the board.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In accordance with an embodiment, there is provided a printed circuit board, including: a first insulation layer including a trench formed therein; an electronic component installed in the trench; a second insulation layer formed above the first insulation layer and the electronic component; and a circuit layer formed on the first insulation layer and on the second insulation layer.

The printed circuit board may further include: a via formed in the first insulation layer and the second insulation layer and configured to be connected with the electronic component and the circuit layer.

The printed circuit board may further include: a build-up layer laminated on a surface of the first insulation layer and the second insulation layer.

The first insulation layer and the second insulation layer may be made of a resin material including glass fiber impregnated therein.

The printed circuit board may further include: a heat-dissipating plate formed in the first insulation layer.

The heat-dissipating plate may be formed by filling a metallic material including a height similar to a height of the electronic component

The heat-dissipating plate may be simultaneously formed when the trench may be formed to embed the electronic component.

The circuit layer may be formed on an external surface of the first insulation layer and on an external surface of the second insulation layer.

In accordance with an embodiment, there is provided a method of manufacturing a printed circuit board, including: forming a metal layer on both surfaces of a carrier member; forming a first metal block by etching the metal layer excluding an area thereof in which an electronic component may be to be installed; forming a first insulation layer to embed the first metal block; separating the carrier member; and forming a trench by etching the first metal block formed on one surface of a laminate separated from the carrier member.

The method may further include: forming a second insulation layer to embed the electronic component; forming a via hole by drilling the first and second insulation layers having the electronic component embedded therein; and forming a circuit layer by filling a metallic material in the via hole and patterning the metallic material.

The forming of the first insulation layer further may include forming a metal layer on both surfaces of the first insulation layer after the first insulation layer may be formed.

The metal layer may be made of copper.

The method may further include: forming a build-up structure by forming an insulation layer and a circuit layer above and below the first and second insulation layers.

A thickness of the metal layer formed on both surfaces of the substrate may correspond to a height of the electronic component.

The method may further include: forming areas in which electronic components are to be installed.

The forming of the metal block further may include forming a heat-dissipating plate.

In the forming of the metal block, the first metal block may be formed through one of a subtractive process, an additive process, which uses electroless copper plating and electrolytic copper plating, and a semi-additive process (SAP).

Other features and aspects will be apparent from the following detailed description, the drawings, and the claims.

### BRIEF DESCRIPTION OF DRAWINGS

FIG. 1 is a cross-sectional view illustrating an example of an electronic component embedded printed circuit board, in accordance with an embodiment.

FIG. 2 through FIG. 7B are cross-sectional views illustrating various examples of an electronic component embedded printed circuit board, in accordance with embodiments.

FIG. 8 is a flow diagram illustrating an example of a method to manufacture an electronic component embedded printed circuit board, in accordance with an embodiment.

FIG. 9A through FIG. 9K illustrate processes to manufacture an electronic component embedded printed circuit board, in accordance with embodiments.

FIG. 10A through FIG. 10N illustrate alternative processes to manufacture an electronic component embedded printed circuit board, in accordance with embodiments.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

Unless otherwise defined, all terms, including technical terms and scientific terms, used herein have the same meaning as how they are generally understood by those of ordinary skill in the art to which the present disclosure pertains. Any term that is defined in a general dictionary shall be construed to have the same meaning in the context of the relevant art, and, unless otherwise defined explicitly, shall not be interpreted to have an idealistic or excessively formalistic meaning.

Terms such as “first” and “second” can be used in describing various elements, but the above elements shall not be restricted to the above terms. The above terms are used only to distinguish one element from the other. In the accompanying drawings, some elements may be exaggerated, omitted or briefly illustrated, and the dimensions of the elements do not necessarily reflect the actual dimensions of these elements.

FIG. 1 is a cross-sectional view illustrating a first example of an electronic component embedded printed circuit board, in accordance with an embodiment. As illustrated in FIG. 1, an electronic component embedded printed circuit board is includes a first insulation layer 110 having a trench formed therein 112, an electronic component 120 installed on a bottom surface of the trench 112 of the first insulation layer 110, and a second insulation layer 115 formed above the first insulation layer 110 including the electronic component 120 installed therein. The electronic component embedded printed circuit board also includes a circuit layer 130 formed on an external surface of the first insulation layer 110 and on an external surface of the second insulation layer 115, the external surface which is opposite to an internal surface of the second insulation layer 115 facing the first insulation layer 110.

The first insulation layer 110 has the trench 112 formed therein such that the electronic component 120 is installed therein. In this example, the first insulation layer 110 is made of a thermosetting or thermoplastic polymer material, a ceramic, an organic or inorganic composite material, or any resin having glass fiber impregnated therein. In an example in which the first insulation layer 110 is made of a polymer resin, the polymer resin includes an epoxy insulation resin, for example, flame retardant 4 (FR-4), bismaleimide triazine (BT) or an ajinomoto build-up film (ABF). Alternatively, the polymer resin includes a polyimide resin.

In this example, in embedding the electronic component 120 in the first insulation layer 110, after the trench 112 is formed in the first insulation layer 110 using a common circuit forming method, the electronic component 120 is installed. The second insulation layer 115 is then formed and laminated such that the electronic component 120 is embedded within the trench 112. The first insulation layer 110 and the second insulation layer 115 are formed in two layers and are made of a same material or different materials.

Moreover, each of the first insulation layer 110 and the second insulation layer 115 has a via 132, which penetrates in a thickness direction, and a micro via 131, to connect with an electrode of the embedded electronic component 120, formed therein using a YAG laser or a CO₂ laser.

The circuit layer 130 is formed using a subtractive process, which uses an etching resist to selectively remove a metallic material formed on an external surface of the first insulation layer 110 and the second insulation layer 115, an additive process, which uses electroless copper plating and electrolytic copper plating, a semi-additive process (SAP), or a modified semi-additive process (MSAP).

The electronic component 120 has an electrode formed on an outer portion of a top surface thereof and on an outer portion of a bottom surface thereof to electrically connect to the circuit layer 130.

The electronic component 120 may be an active device, such as a transistor, an integrated circuit (IC), or a large scale integrated circuit (LSI). The electronic component 120 may be a passive device, such as a resistor, a capacitor, or an inductor.

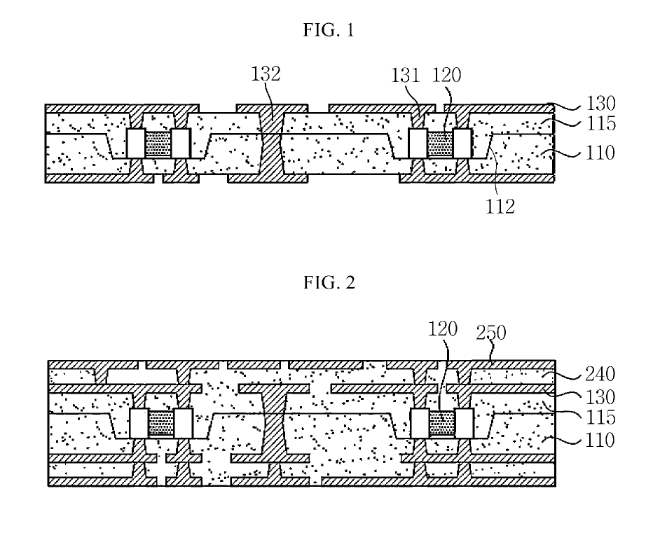

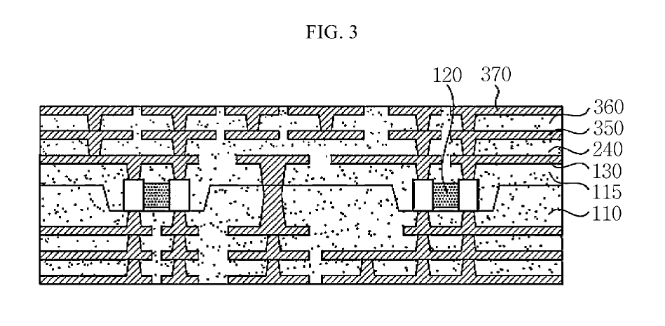

FIG. 2 and FIG. 3 are cross-sectional views illustrating, respectively, second and third examples of an electronic component embedded printed circuit board. FIG. 2 and FIG. 3 show configurations in which layers are additionally laminated on the first example of an electronic component embedded printed circuit board. For instance, the second example has a third insulation layer 240 and a second circuit layer 250 formed therein in addition to the two-layer structure of the first example. The third example has a fourth insulation layer 360 and a third circuit layer 370 formed therein in addition to the structure of the second example. Accordingly, the electronic component embedded printed circuit board, according to an embodiment, may be built up from two layers to four layers and six layers or from three layers to five layers and seven layers. In one example, build-up layers are not restricted to the examples described herein and may be additionally formed as necessary.

FIG. 4 is a cross-sectional view illustrating a fourth example of an electronic component embedded printed circuit board. As illustrated in FIG. 4, the fourth example of an electronic component embedded printed circuit board includes a first insulation layer 410 and a second insulation layer 415 having a metal layer 440 formed thereon and having a via 132 formed therein for electrical connection with each other and micro via 131, to connect with an electrode of the embedded electronic component 120, formed therein using a YAG laser or a CO₂ laser. The electronic component embedded printed circuit board also includes an electronic component 420 embedded in the first insulation layer 410, and a heat-dissipating plate 430 embedded in the first insulation layer 410 with a similar height as that of the electronic component 420. In one embodiment, the similar height is a height in which the first insulation layer 410 has the same height as that of the electronic component 420. In another embodiment, the similar height is a height in which the first insulation layer 410 has a height greater (by 0.1% or greater) or smaller (by 0.1% or greater) than that of the electronic component 420.

Descriptions of any elements that are identical with those of the first example shown in FIG. 1 are incorporated herein.

The heat-dissipating plate 430 is simultaneously formed when a trench 112 is formed using a common circuit forming method in order to embed the electronic component 420. For instance, after a metal block is formed by etching a metal layer that is thickly coated on a carrier member, in order to embed the electronic component, the first insulation layer 410 is coated. Then, the trench 112 is formed by etching the metal block, and the unetched metal block is embedded in the first insulation layer 410 to be formed as the heat-dissipating plate 430.

In an example, the size of the heat-dissipating plate 430 corresponds to the size of the metal block and, in one example, is made of copper, however, other materials may be used, such as any metal having a good heat-dissipating property.

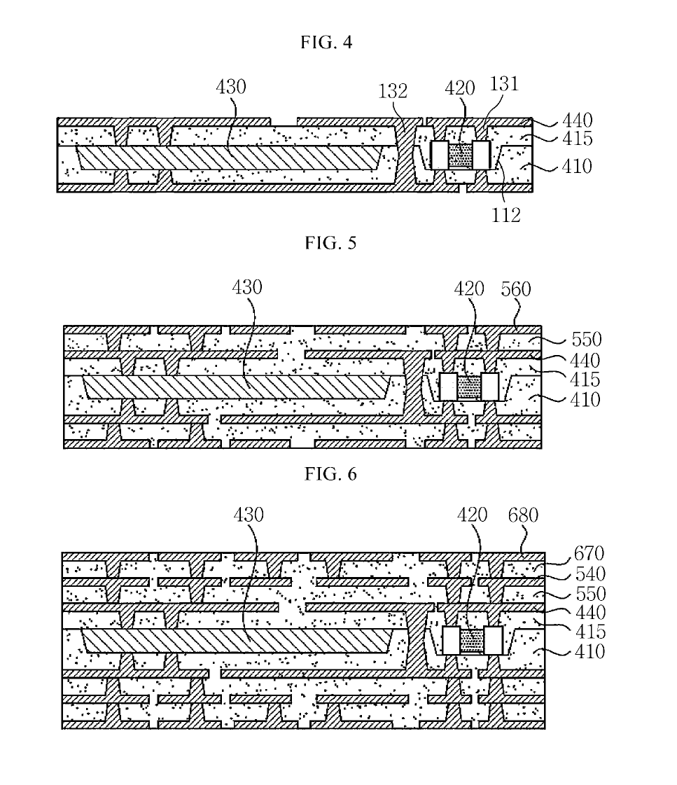

FIG. 5 and FIG. 6 are cross-sectional views illustrating, respectively, a fifth example and a sixth example of an electronic component embedded printed circuit board, in accordance with embodiments. FIG. 5 and FIG. 6 show configurations in which layers are additionally laminated on an electronic component embedded printed circuit board.

For example, the fifth example has a third insulation layer 550 and a second circuit layer 560 formed therein in addition to the two-layer structure of the fourth example. The sixth example has a fourth insulation layer 670 and a third circuit layer 680 formed therein in addition to the structure of the fifth example. Accordingly, the electronic component embedded printed circuit board, according to an embodiment, may be built up from two layers to four layers and six layers or from three layers to five layers and seven layers. In an example, build-up layers are not restricted to the examples described herein and may be additionally formed as needed.

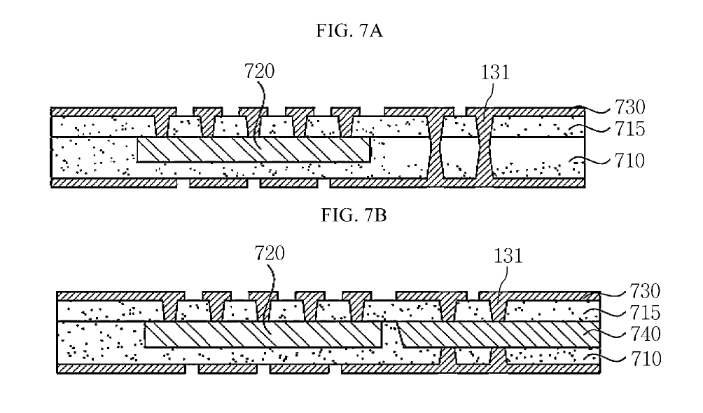

FIG. 7A and FIG. 7B are cross-sectional views illustrating, respectively, a seventh example and an eighth example of an electronic component embedded printed circuit board, in accordance with embodiments. As illustrated in FIG. 7A and FIG. 7B, in which an in-plane switching electronic component 720 is embedded, micro vias 131 are formed in a first insulation layer 710 and a second insulation layer 715, and a heat-dissipating plate 740 is embedded in the first insulation layer 710. The in-plane switching electronic component 720 may be an active device. An outer circuit layer 730 is formed by filling a metallic material in the micro via 131. In this example, the outer circuit layer 730 is formed through a semi-additive process (SAP) or a modified semi-additive process (MSAP). In other words, a two-layered coreless embedded printed circuit board may be formed in the configuration of any of the above-described examples.

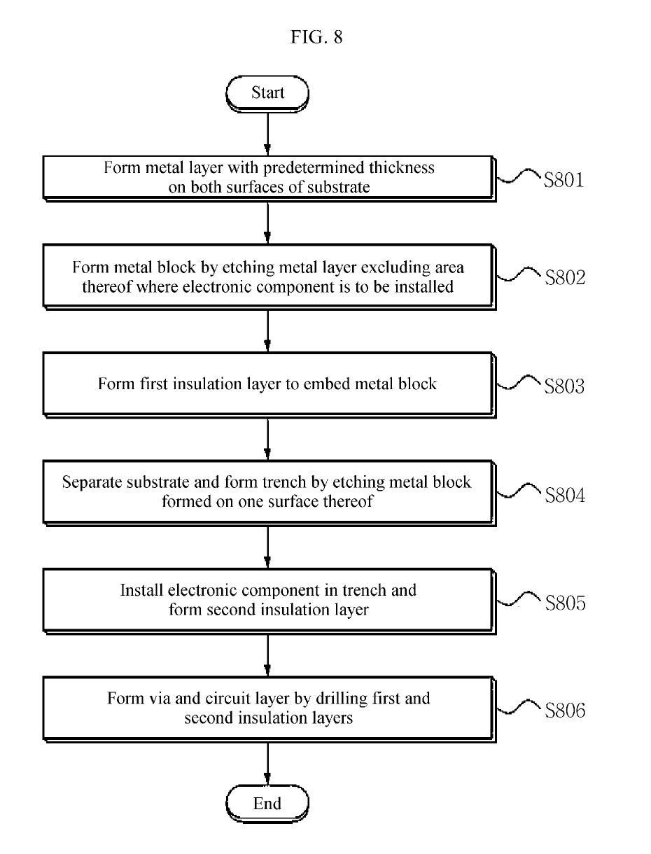

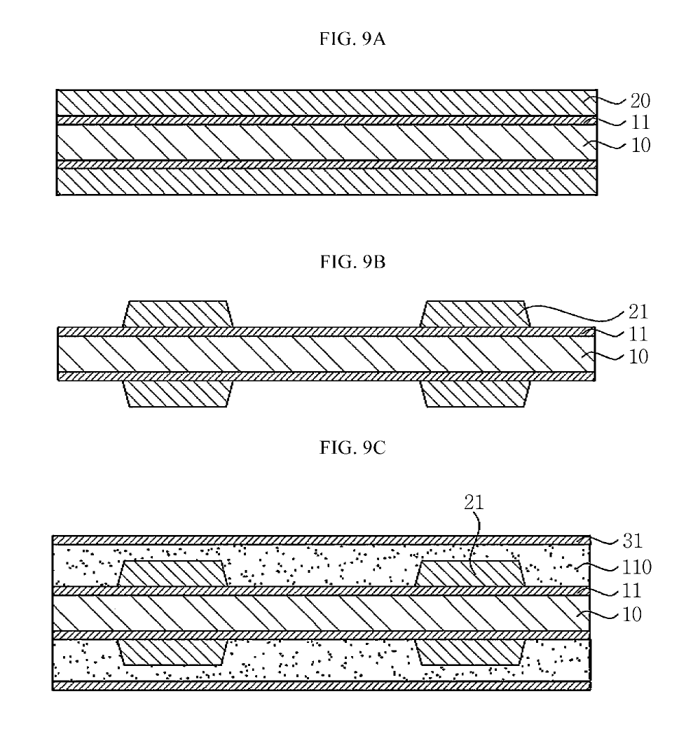

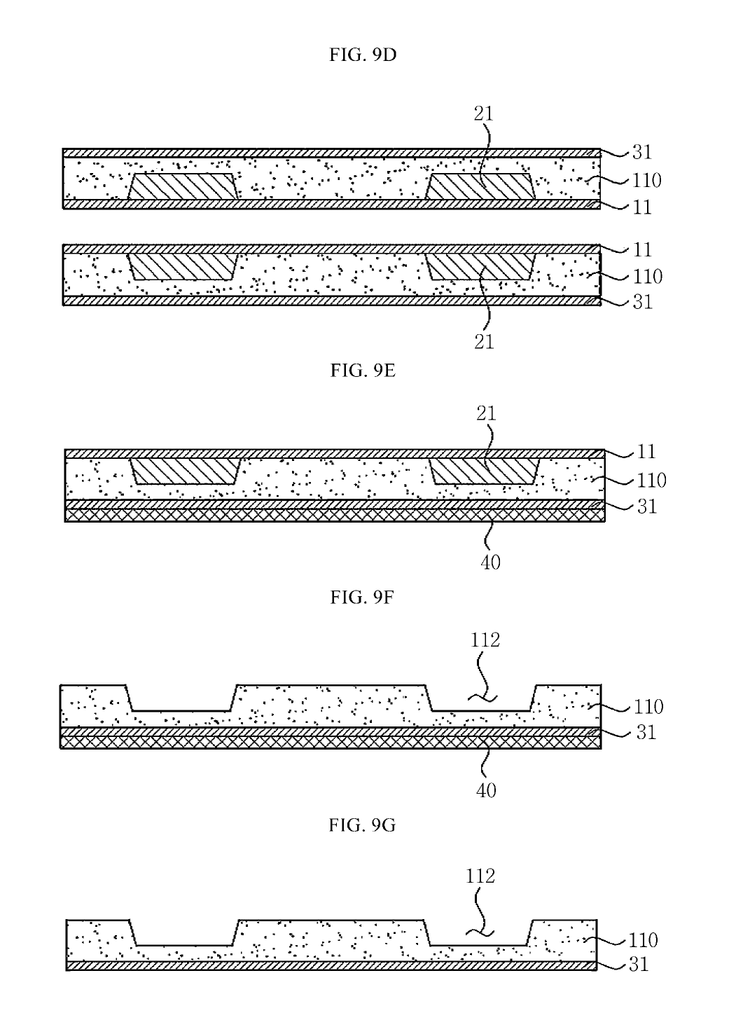

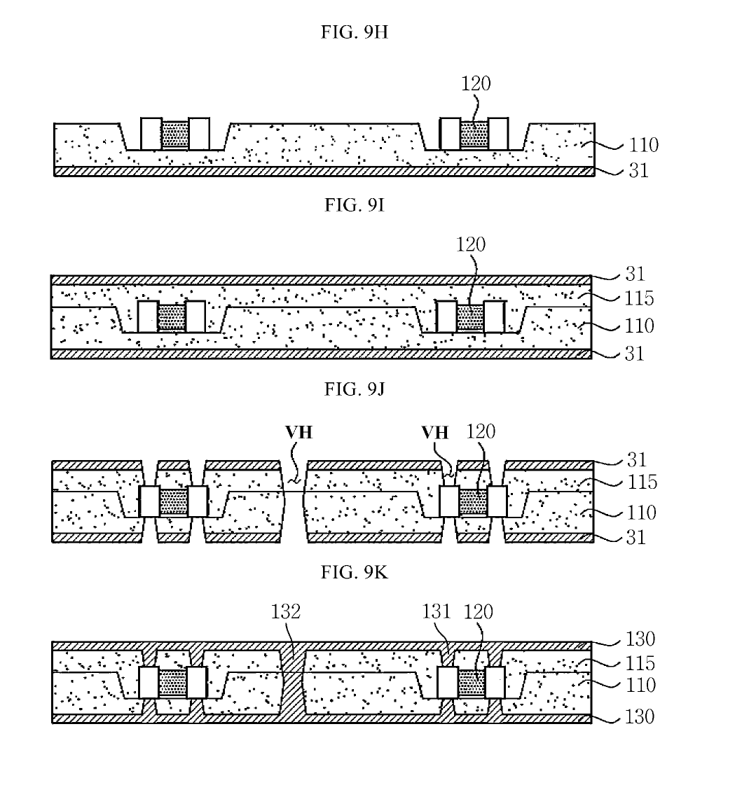

FIG. 8 is a flow diagram illustrating an example of a method of manufacturing an electronic component embedded printed circuit board, in accordance with an embodiment. FIG. 9A through FIG. 9K illustrate processes used in an example of a method to manufacture an electronic component embedded printed circuit board by illustrating cross-sectional views of the electronic component embedded printed circuit board during a manufacturing process, in accordance with embodiments.

As illustrated in FIG. 8, a method of manufacturing an electronic component embedded printed circuit board, according to an embodiment includes, at operation S801, forming a metal layer with a predetermined thickness on both surfaces of a substrate. At operation S802, the method forms a metal block by etching the metal layer, excluding an area thereof where an electronic component is to be installed. At operation S803, the method forms a first insulation layer to embed the metal block and, at operation S804, the method separates the substrate and forms a trench by etching the metal block formed on one surface thereof. At operation S804, the method installs the electronic component in the trench and, at operation S805, forms a second insulation layer to embed the electronic component is embedded. At operation S806, the method forms a via hole and a circuit layer by drilling the first and second insulation layers having the electronic component embedded therein.

Hereinafter, each of the processes used in the method of manufacturing an electronic component embedded printed circuit board according to this embodiment will be further described. In one example, the electronic component embedded printed circuit board used in this example is shown in FIG. 1.

Referring to FIG. 9A, a thick metal layer 20 is formed on both surfaces of a detachable core substrate 10 having a metal foil layer 11 formed on both surfaces thereof. In this example, the metal layer 20 is made of copper in a thickness corresponding to a height of an electronic component 120. That is, in an embodiment, a thickness of the trench in which the electronic component 120 to be installed is the same as the thickness of the metal layer 20. In alternative embodiments, the thickness of the trench may have variations, from 0.1% or greater, from the thickness of the metal layer 20.

Referring to FIG. 9B, a metal block 21 is formed by etching the metal layer 20 according to a location corresponding to where the electronic component 120 is to be installed. In an example, the metal block 21 is formed using a subtractive process, which uses an etching resist to selectively remove a metallic material, an additive process, which uses electroless copper plating and electrolytic copper plating, or a semi-additive process (SAP). That is, the common circuit forming method of etching process is used to remove the metal layer 20, excluding an area where the electronic component 120 is to be installed.

Referring to FIG. 9C, a first insulation layer 110 and a metal foil layer are formed on the substrate having the metal block 21 formed thereon. In an embodiment, first insulation layer 110 is formed by laminating a prepreg. The first insulation layer 110 and a metal foil layer 31 are formed on the substrate having the metal block 21 formed thereon.

Referring to FIG. 9D, an upper plate and a lower plate are separated from the detachable core substrate 10. The following description will be based on the lower plate.

Referring to FIG. 9E and FIG. 9F, a dry film 40 is coated on a bottom surface of the substrate, and a trench 112 is formed by etching the metal block 21. Accordingly, processing and manufacturing costs are lower by forming the trench 112 without an additional drilling process.

Referring to FIG. 9G and FIG. 9H, the dry film 40 on the bottom surface is removed, and then the electronic component 120 is installed in the trench 112.

Referring to FIG. 9I, a second insulation layer 115 is formed such that the electronic component 120 is embedded therein. Accordingly, the second insulation layer 115 is made of an insulation material having a fluid property, for example, a semi-hardened insulation material. In this example, the second insulation layer 115 is formed as a prepreg layer, and is made of a thermosetting or thermoplastic polymer material, a ceramic, an organic or inorganic composite material, or any resin having glass fiber impregnated therein. In an example in which where the second insulation layer 115 is made of a polymer resin, the polymer resin includes an epoxy insulation resin, for example, flame retardant 4 (FR-4), bismaleimide triazine (BT) or an ajinomoto build-up film (ABF). Alternatively, the polymer resin includes a polyimide resin, but the embodiment is not limited thereto.

Referring to FIG. 9J and FIG. 9K, a micro via 131 and a through-via 132 are formed by drilling the first insulation layer 110 and the second insulation layer 115 such that both electrodes of the electronic component 120 are exposed. In this example, the via holes are formed in the insulation layers 110, 115 using a YAG laser or a CO₂ laser.

An outer circuit layer 130 is formed by filling a metallic material in the micro via 131 and the through-via 132. In this example, the outer circuit layer 130 is formed through a semi-additive process (SAP) or a modified semi-additive process (MSAP). Moreover, the various embodiments are not limited to the above-described processes, and it is possible to apply a common circuit forming process, including a subtractive process, the SAP or the MSAP.

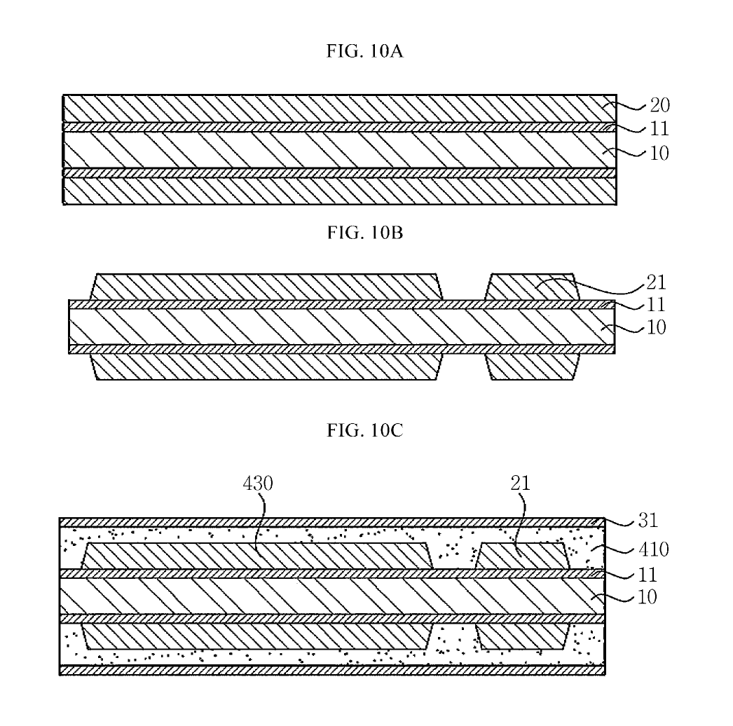

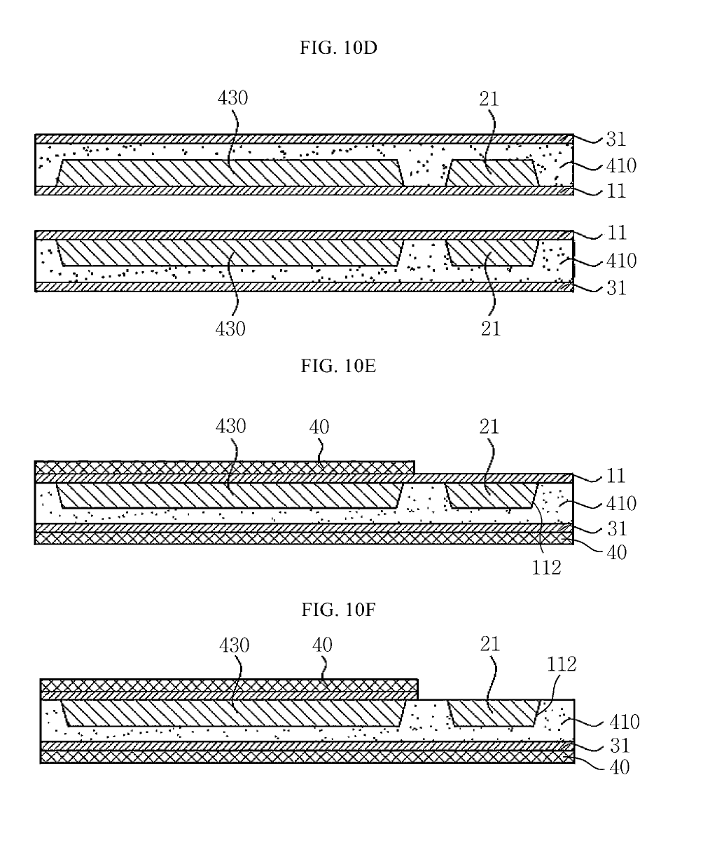

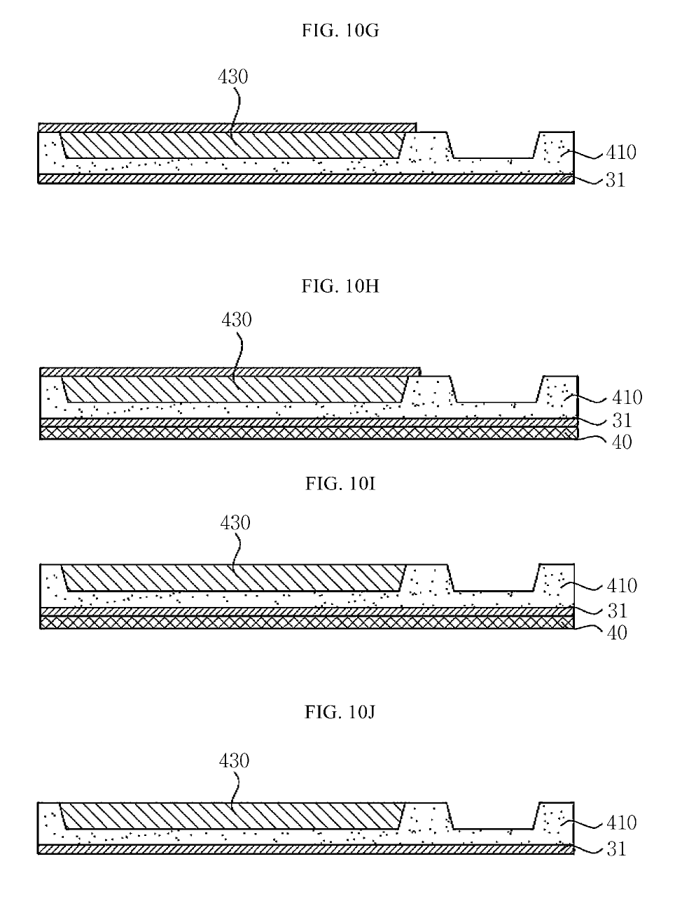

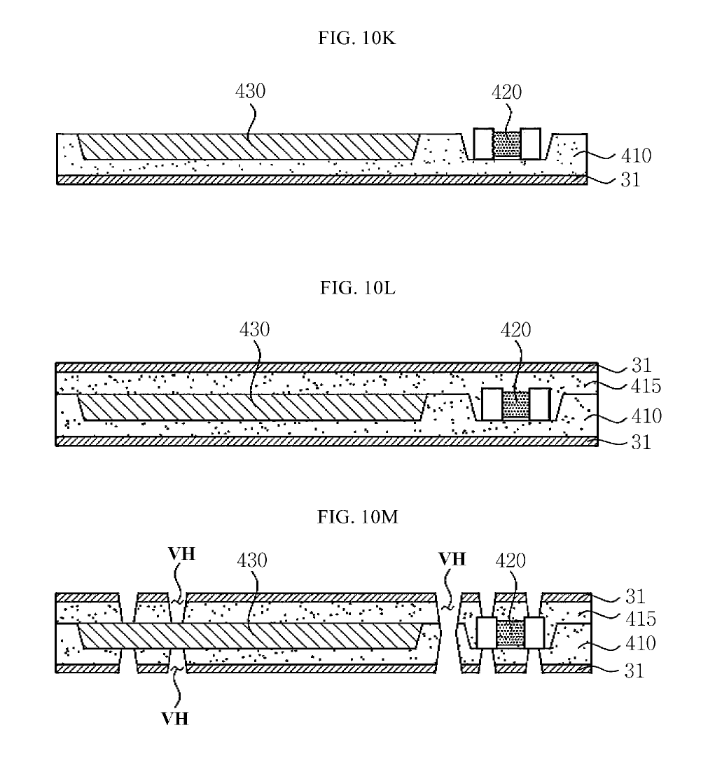

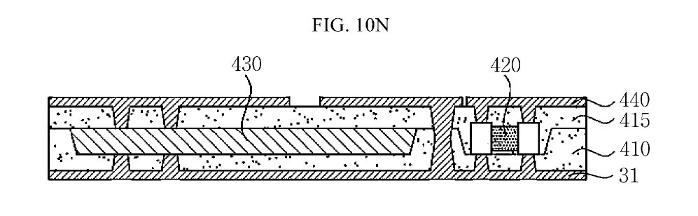

FIG. 10A through FIG. 10N illustrate processes used in another example of a method of manufacturing an electronic component embedded printed circuit board by illustrating cross-sectional views of the electronic component embedded printed circuit board during a manufacturing process, in accordance with an embodiment. In these embodiments, structural elements illustrated in the figures and previously described are incorporated herein.

Referring to FIG. 10A to FIG. 10D, a thick metal layer 20 is formed on both surfaces of a detachable core substrate 10 having a metal foil layer 11 formed on both surfaces thereof. In this example, the metal layer 20 is made of copper in a thickness corresponding to a height of an electronic component 420. That is, a thickness of a heat-dissipating plate 430, which is to be later formed, and a thickness of a trench, in which the electronic component 420 is to be received or installed, are the thickness of the metal layer 20.

A metal block 21 is formed by etching the metal layer 20 at a location according to a size of the heat-dissipating plate 430 and a location corresponding to where the electronic component 420 is to be received or installed. In an example, the metal block 21 is formed using a subtractive process, which uses an etching resist to selectively remove a metallic material, an additive process, which uses electroless copper plating and electrolytic copper plating, or a semi-additive process (SAP). That is, the common circuit forming method of etching process is used to remove the metal layer 20, excluding an area where the electronic component 420 is to be received or installed.

A first insulation layer 410 and the metal foil layer 31 are formed on the substrate having the metal block 21 formed thereon. The first insulation layer 410 is formed by laminating a prepreg.

Then, an upper plate and a lower plate are separated from the detachable core substrate 10. The following description will be based on the lower plate.

Referring to FIG. 10E through FIG. 10F, a dry film 40 is coated on a portion of a top surface of the substrate that corresponds to a location of the metal block 21 that will become the heat-dissipating plate 430 and on a bottom surface of the substrate. A trench 112 is formed by etching the metal block 21 at a location where the electronic component 420 is to be installed. Then, after removing the dry film 40 on the top and bottom surfaces, the electronic component 420 is installed in the trench 112.

Referring to FIG. 101 through FIG. 10N, a second insulation layer 415 is formed such that the electronic component 420 is embedded therein. Accordingly, the second insulation layer 415 is made of an insulation material having a fluid property, such as, a semi-hardened insulation material. In this example, the second insulation layer 415 is formed as a prepreg layer, and is made of a thermosetting or thermoplastic polymer material, a ceramic, an organic or inorganic composite material, or any resin having glass fiber impregnated therein. In an example where the second insulation layer 415 is made of a polymer resin, the polymer resin includes an epoxy insulation resin, for example, flame retardant 4 (FR-4), bismaleimide triazine (BT) or an ajinomoto build-up film (ABF). Alternatively, the polymer resin includes a polyimide resin, but other resins may be used.

Then, a micro via hole and a through-via hole are formed by drilling the first insulation layer 410 and the second insulation layer 415 such that both electrodes of the electronic component 420 are exposed. In this example, the via holes are formed in the insulation layers 410, 415 using a YAG laser or a CO₂ laser.

An outer circuit layer 440 is formed by filling a metallic material in the micro via hole and the through-via hole. In this example, the outer circuit layer 440 is formed through a semi-additive process (SAP) or a modified semi-additive process (MSAP). Moreover, the various embodiments are not limited to the above-described processes, and it is possible in the alternative to apply a common circuit forming process, including a subtractive process, the SAP or the MSAP.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A printed circuit board, comprising:
a first insulation layer comprising a trench formed therein;
an electronic component installed in the trench;
a second insulation layer formed above the first insulation layer and the electronic component; and
a circuit layer formed on the first insulation layer and on the second insulation layer.

2. The printed circuit board as set forth in claim 1, further comprising:
a via formed in the first insulation layer and the second insulation layer and configured to be connected with the electronic component and the circuit layer.

3. The printed circuit board as set forth in claim 1, further comprising:
a build-up layer laminated on a surface of the first insulation layer and the second insulation layer.

4. The printed circuit board as set forth in claim 1, wherein the first insulation layer and the second insulation layer are made of a resin material comprising glass fiber impregnated therein.

5. The printed circuit board as set forth in claim 1, further comprising:
a heat-dissipating plate formed in the first insulation layer.

6. The printed circuit board as set forth in claim 5, wherein the heat-dissipating plate is formed by filling a metallic material comprising a height similar to a height of the electronic component

7. The printed circuit board as set forth in claim 5, wherein the heat-dissipating plate is simultaneously formed when the trench is formed to embed the electronic component.

8. The printed circuit board as set forth in claim 1, wherein the circuit layer is formed on an external surface of the first insulation layer and on an external surface of the second insulation layer.

9. A method of manufacturing a printed circuit board, comprising:
forming a metal layer on both surfaces of a carrier member;
forming a first metal block by etching the metal layer excluding an area thereof in which an electronic component is to be installed;
forming a first insulation layer to embed the first metal block;
separating the carrier member; and
forming a trench by etching the first metal block formed on one surface of a laminate separated from the carrier member.

10. The method as set forth in claim 9, further comprising:
forming a second insulation layer to embed the electronic component;
forming a via hole by drilling the first and second insulation layers having the electronic component embedded therein; and
forming a circuit layer by filling a metallic material in the via hole and patterning the metallic material.

11. The method as set forth in claim 9, wherein the forming of the first insulation layer further comprises forming a metal layer on both surfaces of the first insulation layer after the first insulation layer is formed.

12. The method as set forth in claim 9, wherein the metal layer is made of copper.

13. The method as set forth in claim 10, further comprising:
forming a build-up structure by forming an insulation layer and a circuit layer above and below the first and second insulation layers.

14. The method as set forth in claim 9, wherein a thickness of the metal layer formed on both surfaces of the substrate corresponds to a height of the electronic component.

15. The method as set forth in claim 9, further comprising:
forming areas in which electronic components are to be installed.

16. The method as set forth in claim 9, wherein the forming of the metal block further comprises forming a heat-dissipating plate.

17. The method as set forth in claim 9, wherein in the forming of the metal block, the first metal block is formed through one of a subtractive process, an additive process, which uses electroless copper plating and electrolytic copper plating, and a semi-additive process (SAP).
